(19) United States
(12) Patent Application Publication
(10) Pub. No.: US 2017/0250334 A1
(43) Pub. Date: Aug. 31, 2017

(54) THERMO-COMPRESSION BONDING OF THERMOELECTRIC MATERIALS

(71) Applicant: BASF SE, Ludwigshafen (DE)

(72) Inventors: Wilfried HERMES, Karlsruhe (DE); Markus SCHWIND, Antwerpen (BE); Juergen MOORS, Bonheiden (BE); Mathias WEICKERT, Ludwigshafen (DE)

(73) Assignee: BASF SE, Ludwigshafen (DE)

(21) Appl. No.: 15/512,116

(22) PCT Filed: Sep. 17, 2015
(86) PCT No.: PCT/EP2015/071271

§ 371 Date: Mar. 17, 2017

(30) Foreign Application Priority Data
Sep. 18, 2014 (EP) 14185294.7

(51) Int. Cl. H01L 35/34; H01L 35/22; H01L 35/08

(52) U.S. Cl. CPC H01L 35/34; H01L 35/08; H01L 35/22

(57) ABSTRACT

The invention relates to the use of thermo-compression bonding (TCB) for bonding electrically conductive contacts to thermoelectric material pieces, respective processes and thermoelectric modules which are suitable for fitting in the exhaust system of an internal combustion engine.

### DESCRIPTION

The invention relates to the use of thermo-compression bonding (TCB) for bonding electrically conductive contacts to thermoelectric material pieces, respective processes and thermoelectric modules which are suitable for fitting in the exhaust system of an internal combustion engine.

Thermoelectric generators and Peltier arrangements per se have been known for a long time. p- and n-doped semiconductors, which are heated on one side and cooled on the other side, transport electric charges through an external circuit, so that electrical work can be performed on a load in the circuit. The efficiency thereby achieved for the conversion of heat into electrical energy is thermodynamically limited by the Carnot efficiency.

If on the other hand a direct current is applied to such an arrangement, then heat is transported from one side to the other side. Such a Peltier arrangement works as a heat pump and is therefore suitable for cooling equipment parts, vehicles or buildings. Heating by means of the Peltier principal is also more favorable than conventional heating, because more heat is always transported than corresponds to the energy equivalent supplied.

At present, thermoelectric generators are used in space probes for the generation of direct currents, for the cathodic corrosion protection of pipelines, for the energy supply of light and radio buoys, and for the operation of radios and televisions. The advantages of thermoelectric generators reside in their extreme reliability. They operate irrespective of atmospheric conditions such as relative humidity; no material transport susceptible to interference takes place, rather only charge transport.

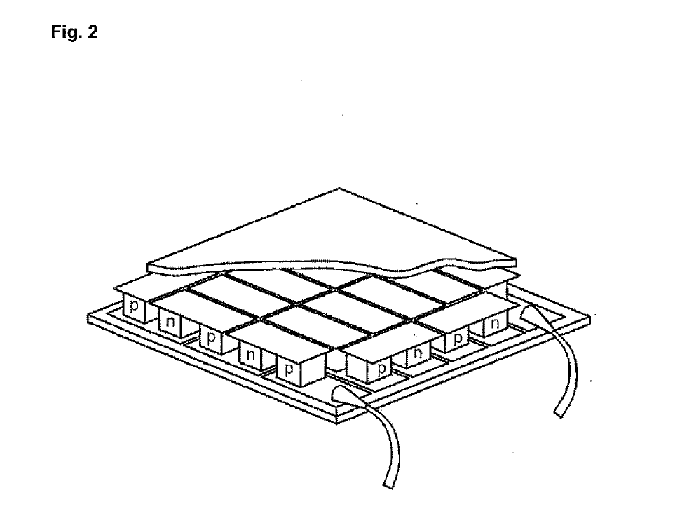

A thermoelectric module consists of p- and n-type pieces which are connected electrically in series and thermally in parallel. FIG. 2 shows such a module.

The conventional structure consists of two ceramic plates, between which the individual pieces are fitted alternately. Two pieces are in each case contacted electrically conductively via the end faces.

Besides the electrically conductive contacting, various further layers are normally also provided on the actual material, which serve as protective layers or as solder layers. Lastly, however, the electrical contact between two pieces is established via a metal bridge.

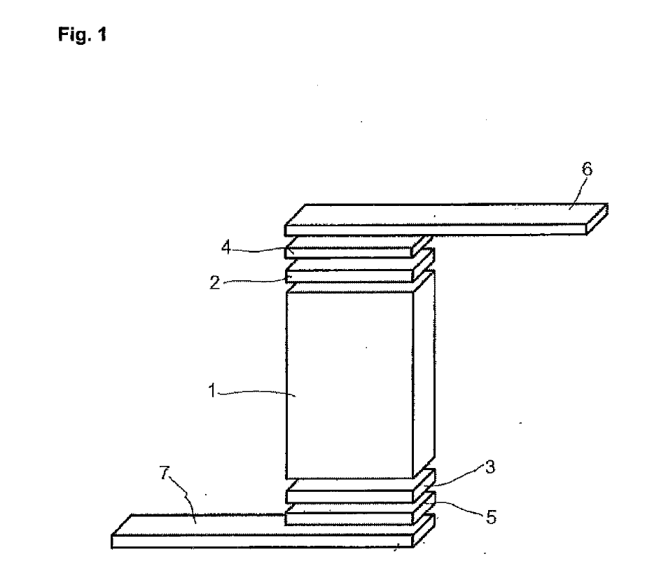

An essential element of thermoelectric components is the contacting. The contacting establishes the physical connection between the material in the “heart” of the component (which is responsible for the desired thermoelectric effect of the component) and the “outside world”. The structure of such a contact is schematically represented in FIG. 1.

The thermoelectric material 1 inside the component provides the actual effect of the component. It is a thermoelectric piece. An electric current and a heat flux flow through the material 1 in order for it to fulfill its function in the overall structure.

The material 1 is connected on at least two sides via the contacts 4 and 5 to the leads 6 and 7, respectively. 4/5 and 6/7 could be the same material, in other words identically, or 4/5 are optional. The layers 2 and 3 are in this case intended to symbolize one or more optionally required intermediate layers (barrier material, solder, bonding agent etc.) between the material and the contacts 4 and 5. More optional layers could be implemented. The segments 2/3, 4/5, 6/7 respectively associated with one another pairwise may be identical, although they do not have to be. This will in the end depend likewise on the specific structure and the application, as well as the flow direction of electric current or heat flux through the structure. The material 1 could be segmented into different thermoelectric materials. At the cold side a low temperature thermoelectric material and at the hot side a high temperature thermoelectric material.

The contacts 4 and 5 now have an important role. They ensure a tight connection between material and leads. If the contacts are poor, then high losses occur here and can greatly restrict the performance of the component. For this reason, the pieces and contacts are often pressed onto the material for use. The contacts are thus exposed to a strong mechanical load. This mechanical load increases further whenever elevated (or reduced) temperatures and/or thermal cycling are involved. The thermal expansion of the materials built into the component inevitably leads to mechanical stresses, which in the extreme case lead to failure of the component by fracture of the contact.

In order to prevent this, the contacts used must have a certain flexibility and resilient properties, so that such thermal stresses can be compensated for.

In order to impart stability to the entire structure, and ensure the required maximally homogeneous thermal coupling over every one of the pieces, carrier plates are necessary. To this end a ceramic is conventionally used, for example made of oxides or nitrides such as Al₂O₃, SiO₂ or AlN.

The conventional structure is often subject to limitations in respect of an application, since in each case only planar surfaces can be brought in contact with the thermoelectric module. A tight connection between the module surface and the heat source/heat sink is indispensable in order to ensure a sufficient heat flux.

Currently, attempts are being made to provide thermoelectric modules in motor vehicles such as automobiles and trucks, in the exhaust system or the exhaust gas recirculation, in order to obtain electrical energy from a part of the exhaust gas heat. In this case, the hot side of the thermoelectric element is connected to the exhaust gas or tailpipe, while the cold side is connected to a cooler. The amount of electricity which can be generated depends on the temperature of the exhaust gas and the heat flux from the exhaust gas to the thermoelectric material. In order to maximize the heat flux, devices are often built into the tailpipe. These are subject to limitations, however, since for example the installation of a heat exchanger often leads to a pressure loss in the exhaust gas, which in turn leads to an intolerable increased consumption of the internal combustion engine.

Conventionally, the thermoelectric generator is installed for use behind the exhaust gas catalytic converter in the exhaust system. Together with the pressure loss of the exhaust gas catalytic converter, this often leads to excessive pressure losses so that thermally conductive devices cannot be provided in the exhaust system; rather, the thermoelectric module bears on the outside of the tailpipe. To this end, the tailpipe must often be configured with a polygonal cross section so that planar external surfaces can come in tight contact with the thermoelectric material.

WO 2013/050961 discloses an integrated assembly of micro heat exchanger and thermoelectric module, wherein the thermoelectric module is thermally conductively connected to the micro heat exchanger. The micro heat exchanger has an integrally molded container which receives the p- and n-conducting thermoelectric material pieces.

Thermoelectric generators based on silicides and half-Heusler compounds are known per se, for example from DE 10 2013 004 173 B3.

The thermoelectric materials can be contacted by soldering or mechanically connecting.

H. T. Kaibe et al. describe in ICT-2004

(http://www.thermoelectricss.com/th/paper/ict04_komatsu.pdf) the development of thermoelectric generating cascade modules using silicide and Bi-Te. p-type Mn-Si and n-type Mg-Si are employed for module fabrication. It is generally stated that there are three major strategies for module fabrication, namely soldering (or brazing), thermal spray or mechanical contacting. Thermal spray technique was employed to form the metallic electrodes such as Al and Cu.

H. T. Kaibe et al. describe in Journal of Thermoelectricity No. 1, 2009, pages 59 to 67, the performance of silicide modules using n-type Mg-Si and p-type Mn-Si. Higher manganese silicide (HMS) was used together with MnSi_{1.74} with proper amount of dopant material such as Mo, Al and Ge. To form the metallic electrode such as Al and Cu on the thermoelectric materials, the thermal spray technique was employed. It is suggested that a thermal spray be a promising technique to form a superior metallic electrodes in terms of both electrically and thermally low contact resistances.

As an alternative, normal soldering technique was employed to connect Ni-plated Cu electrodes.

The use of the described techniques for bonding electrically conductive contacts to thermoelectric material pieces is not under all circumstances satisfactory since sometimes there is no proper balance between electrical, mechanical and thermal properties.

Furthermore, the known thermoelectric modules based on silicides are not fully optimized for use in a motor vehicle exhaust gas system.

The object underlying the present invention is firstly to provide an improved bonding of electrically conductive contacts to thermoelectric material pieces and secondly to adapt silicide-based thermoelectric modules for implementation in a motor vehicle exhaust gas system.

The objects are achieved according to the present invention by the use of thermo-compression bonding (TCB) for bonding electrically conductive contacts to thermoelectric material pieces.

The objects are furthermore achieved by a process for forming a thermo-electric module comprising p- and n-conducting thermoelectric material pieces which are ultimately connected to one another via electrically conductive contacts, wherein the electrically conductive contacts are connected to the thermoelectric material pieces by thermo-compression bonding.

The objects are furthermore achieved by a thermoelectric module comprising of p- and n-conducting thermoelectric material pieces which are alternately connected to one another via electrically conductive contacts, wherein the electrically conductive contacts are connected to the thermoelectric material pieces by thermo-compression bonding.

According to the present invention it has been found that thermo-compression bonding (TCB), sometimes also called thermo-compressed bonding (“Diffusionsschweiβen” in German language) is a superior way for bonding electrically conductive contacts to thermoelectric material pieces.

The thermo-compression bonding (TCB)-technique is known per se. This term describes a metal bonding technique and is also referred to as diffusion bonding, pressure joining, thermo-compression welding or solid-state welding. Two metals, e. g. gold (Au)-gold (Au), are brought into atomic contact applying force and heat simultaneously. The diffusion requires atomic contact between the surfaces due to the atomic motion. The atoms migrate from one crystal lattice to the other one based on crystal lattice vibration. This atomic interaction sticks the interface together. The diffusion process is described by the following three processes: surface diffusion, grain boundary diffusion, and bulk diffusion.

The specific parameters of the thermo-compression bonding can be adapted to the respective thermoelectric material and choice of electrically conductive contact material.

Generally, the thermo-compression bonding is performed at a maximum temperature well below the melting point and/or decomposition temperature of the thermoelectric materials involved, whichever is lowest, and below the lowest melting point and/or decomposition temperature of the conduction material(s). Preferably, the maximum temperature should be in the range from 10° C. to 500° C. below the lowest melting point and/or decomposition temperature, more preferably in the range from 50° C. to 100° C. The time for which this maximum temperature is applied is preferably in the range from 5 to 180 min., more preferably in the range from 10 to 60 min., most preferably in the range from 10 to 30 min.

Using Al clad stainless steel as conduction material on MnSi_{1.7}, Mg₂Si and/or (Ti_{1-x-y}ZrₓHf_{y})NiSn_{1-w}Sb_{w} as thermoelectric material, the thermo-compression bonding is performed at a maximum temperature in the range of 550 to 650° C., more preferably in the range of 570 to 600° C., most preferably in the range of 570 to 590° C. The time for which this maximum temperature is applied is preferably in the range from 5 to 60 min., more preferably in the range from 10 to 30 min., most preferably in the range from 10 to 20 min.

Typically, a temperature profile is chosen in which the thermoelectric material pieces and electrically conductive contact materials are heated from room temperature to the maximum temperature first, the maximum temperature is held for an appropriate time, and then the system is cooled over a prolonged period of time till room temperature (ambient temperature) is reached again. Typically, the increase from room temperature (ambient temperature) to maximum temperature can be within 1 to 5 hours, more preferably within 2 to 3 hours. The decline of the temperature can be prolonged and cover time periods of up to 50 h, preferably being in the range of from 5 to 30 h, more preferably in the range from 15 to 25 h.

The pressure applied during thermo-compression bonding is preferably in the range of from 10 to 10.000 bar (abs.), more preferably in the range of from 100 to 5000 bar (abs.), most preferably in the range of from 150 to 1000 bar (abs.). The pressure applied should be well below the compressive stability limit of any of the thermoelectric materials involved.

For MnSi_{1.7}, the compressive stability limit is 3000 bar, for Mg₂Si 2500 bar, for (Ti_{1-x-y}ZrₓHf_{y})NiSn_{1-w}Sb_{w} 2500 bar. Using Al clad stainless steel as conduction material on MnSi_{1.7}, Mg₂Si and/or (Ti_{1-x-y}ZrₓHf_{y})NiSn_{1-w}Sb_{w} as thermoelectric material, the pressure applied is preferably in the range from 100 to 1000 bar, more preferably in the range from 200 to 500 bar.

The thermo-compression bonding is preferably performed under inert or reductive cover gas. The cover gas can for example be argon, argon/hydrogen, nitrogen or nitrogen/hydrogen. Other cover gas types which do not oxidize the thermoelectric material pieces and the electrically conductive contacts can also be employed. Preferably, argon/(1 to 10%) hydrogen cover gas is employed.

By employing thermo-compression bonding for bonding the electrically conductive contacts to thermoelectric material pieces, a very strong bond between the thermoelectric material pieces and the electrically conductive contacts is formed. Typically, when excessive mechanical stress is applied, the thermoelectric material pieces will break but not the bond between the thermoelectric material pieces and the electrically conductive contacts.

The electrically conductive contacts can be chosen from a wide variety of metals, metal alloys or metal composite materials. Preferably, the electrically conductive contacts are chosen from Al, Cu, Ag, Au, Fe, Mo, Si, Pd, Cr, Co, Ni, Ti, W and alloys such as stainless steel or composite material of two or more thereof. A particularly preferred electrically conductive contact material is one electrically conductive material cladded on another electrically conductive material, more preferably aluminum clad steel (vide supra). Aluminum clad steel can be obtained from various sources, for example under the trade mark Feran® from Wickeder Westfalenstahl. Feran® is produced by cladding steel with aluminum either on one side or both sides. Preferably, single sided aluminum clad mild steel is employed, wherein the total thickness can be in the range of from 0.2 to 2.0 mm, more preferably 0.3 to 1.0 mm, especially 0.5 to 0.7 mm. For a Feran® thickness of 0.6 mm, typically 0.35 mm of steel are cladded with 0.25 mm of aluminum.

The Feran® is typically applied in a way that the aluminum cladded side faces the thermoelectric material pieces. The use of Feran® is advantageous over the use of Al in that the mechanical stability is increased and deformation, breakage and loss of electrical contact can be avoided.

The electrically conductive contacts can be directly bonded to the thermoelectric material itself. Furthermore, it is possible and sometimes advantageous to cover the thermoelectric material (pieces) with additional layers before contacting. As described above in the introductory part, intermediate layers, like barrier material etc., can be present between the material and the contacts.

According to one embodiment of the invention, the thermoelectric material (pieces) are coated with metals or metal alloys chosen from Al, Cu, Ag, Au, Fe, Mo, Si, Pd, Cr, Co, Ni, Ti, W and alloys such as stainless steel before connecting the electrically conductive contacts thereto.

According to the present invention a wide variety of thermoelectric materials can be employed as described below. A wide variety of materials is for example described in DE 199 55 788 A1.

Preferably, the thermoelectric material is chosen from silicides and half-Heusler materials, more preferably from magnesium silicides, manganese silicides, half-Heusler compounds of the general formular (Ti_{1-x-y}ZrₓHf_{y})NiSn_{1-w}Sb_{w} with 0<=x and y<=1 and 0<=w<0.2 and Ti CoSb and substitution variants hereof Silicides and half-Heusler materials can contain one or more dopants in order to modify the thermoelectric properties, mechanical properties or both. Silicides and half-Heusler Materials which can be employed according to the present invention are for example described in the documents listed above in the introductory part of the specification. Reference can especially be made to DE 10 2013 004 173 B3, paragraphs [0011] to [0014]. Ways to optimize the amount of dopant addition and the application of an optional surface coating for Mg-Si-based thermoelectric elements and Mn-Si-based thermoelectric elements is for example described in KOMATSU Technical Report 2003, Vol. 49, no. 152, pages 1 to 7, specifically section 2.2.

p-type Mn-Si, specifically MnSi_{1.73} with proper amount of dopant materials such as Mo, Al and Ge as well as n-type Mg-Si, specifically Mg₂Si_{0.4}Sn_{0.6} doped with certain amount of Sb are described in ICT-2004 (http://www.thermoelectricss.com/th/paper/ict04_komatsu.pdf).

Several manganese silicides such as MnSi and Mn₅Si₃ as well as Mn₄Si_{7,} Mn₁₅Si₂₆ or MnSi_{1.74} as well as higher manganese silicides (HMS) are described in the Journal of Thermoelectricity No. 1, 2009, pages 59 to 67, specifically section 2. Possible dopant materials listed are Mo, Al and Ge.

In the Journal of Electronic Materials 2014 (DOI: 10.1007/s11664-013-2940-1), Y. Thimont et al. describe the design of apparatus for Ni/Mg₂Si and Ni/MnSi_{1.75} contact resistance determination for thermoelectric legs. Mg₂Si_{0.98}Bi_{0.02} and MnSi_{1.75}Ge_{0.02} are described and metallized with nickel foils.

Magnesium silicides are furthermore disclosed in DE-A-2 165 169. Mangan silicides are furthermore disclosed in DE-A-1 298 286.

Several half-Heusler materials are described in US patent application 2012/0037199A1 and DE patent application DE10 2013 004 173 B3.

A thermoelectric module for installation in the exhaust system of an internal combustion engine, which avoids the disadvantages of the known modules and ensures better heat transfer with a low pressure loss and an easier assembly, is one, wherein the thermoelectric module (19) is thermally conductively connected to a micro heat exchanger (13) which comprises a plurality of continuous channels having a diameter of at most 1 mm, through which a fluid heat exchanger medium can flow.

The thermoelectric modules are connected to the heat exchanger. This connection can either be a connection as chemically bonded or mechanically bonded by an applied pressure.

One way to realize this, is that the micro heat exchanger (13) is formed integrally with the thermoelectric module (19) in a way that the micro heat exchanger (13) has an integrally molded container which receives the p- and n-conducting thermoelectric material pieces which are alternately connected to one another via electrically conductive contacts, to form an integrated assembly of micro heat exchanger (13) and thermoelectric module (19). This set-up is described in WO 2013/050961 or WO 2012/046170.

It is particularly advantageous for the channels of the micro heat exchanger to be coated with a washcoat of an internal combustion engine exhaust gas catalyst, in particular a motor vehicle exhaust gas catalyst. In this way, a separate exhaust gas catalytic converter can be obviated and the pressure loss in the exhaust system is minimized. The integrated design simplifies the overall structure and facilitates installation in the exhaust system.

By using micro heat exchangers, it is possible to ensure an improved heat flux from the exhaust gas to the thermoelectric module, with at the same time a sufficiently low pressure loss. According to the invention, the exhaust gas flows through the microchannels of the micro heat exchanger. The channels are in this case preferably coated with an exhaust gas catalyst, which in particular catalyzes one or more of the conversions: NOₓ to nitrogen, hydrocarbons to CO₂ and H₂O, and CO to CO_{2.} Particularly preferably, all these conversions are catalyzed.

Suitable catalytically active materials such as Pt, Ru, Ce, Pd are known, and are described for example in Stone, R. et al., Automotive Engineering Fundamentals, Society of Automotive Engineers 2004. These catalytically active materials are applied in a suitable way onto the channels of the micro heat exchanger. Preferably, application in the form of a washcoat may be envisaged. In this case, the catalyst is applied in the form of a suspension as a thin layer onto the inner walls of the micro heat exchanger, or onto its channels. The catalyst may then consist of a single layer or various layers with identical or varying composition. The applied catalyst may then fully or partially replace the normally used exhaust gas catalytic converter of the internal combustion engine during use in a motor vehicle, depending on the dimensioning of the micro heat exchanger and its coating.

According to the invention, the term “micro heat exchanger” is intended to mean heat exchangers which have a plurality of continuous channels with a diameter of at most 1 mm, particularly preferably at most 0.8 mm. The minimum diameter is set only by technical feasibility, and is preferably of the order of 50 μm, particularly preferably 100 μm.

The channels may have any suitable cross section, for example round, oval, polygonal such as square, triangular or star-shaped, etc. Here, the shortest distance between opposite edges or points of the channel is considered as the diameter. The channels may also be formed so as to be flat, in which case the diameter is defined as the distance between the bounding surfaces.

This is the case in particular for heat exchangers which are constructed from plates or layers. In this case, the container is integrally molded with at least one of these plates or layers. During operation, a heat exchanger medium flows through the continuous channels while transferring heat to the heat exchanger. The heat exchanger is on the other hand integrally molded and thus thermally connected to the thermoelectric module, so that good heat transfer is obtained from the heat exchanger to the thermoelectric module.

The micro heat exchanger and container may be constructed in any suitable way from any suitable materials. It may for example be made from a block of a thermally conductive material, into which the continuous channels and the container are introduced.

Any suitable materials may be used as the material, such as plastics, for example polycarbonate, liquid crystal polymers such as Zenith® from DuPont, polyether ether ketones (PEEK), etc. Metals may also be used, such as iron, copper, aluminum or suitable alloys such as chromium-iron, Fecralloy. Ceramics or inorganic oxide materials may furthermore be used, such as aluminum oxide or zirconium oxide or cordierite. It may also be a composite material made of a plurality of the aforementioned materials. The micro heat exchanger is preferably made of a high temperature-resistant alloy (1000-1200° C.), Fecralloy, iron alloys containing Al, stainless steel, cordierite. The microchannels may be introduced into a block of a thermally conductive material in any suitable way for example by laser methods, etching, boring, etc.

As an alternative, the micro heat exchanger and container may also be constructed from different plates, layers or tubes, which are subsequently connected to one another, for example by adhesive bonding or welding. The plates, layers or tubes may in this case be provided in advance with the microchannels and then assembled. In this case, the container which receives the p- and n-conducting thermoelectric material pieces is integrally molded to at least one of the plates, layers or tubes.

It is particularly preferred to produce the micro heat exchanger and container from a powder by means of a sintering method. Both metal powders and ceramic powders can be used as the powder. Mixtures composed of metal and ceramic, composed of different metals or composed of different ceramics are also possible. Suitable metal powders comprise, for example, powders composed of ferritic steels, Fecralloy or stainless steel. The production of the micro heat exchanger by means of a sintering method makes it possible to manufacture any desired structure.

Most preferably, the micro heat exchanger (13) which has the integrally molded container is formed by Selective Laser Sintering (SLS). This allows for the easy assembly of the integrated micro heat exchanger/thermoelectric module container-system with nearly any desirable three-dimensional shape or structure. Selective Laser Sintering techniques are known to a person skilled in the art.

The use of a metal as material for the micro heat exchanger and container affords the advantage of a good thermal conductivity. By contrast, ceramics have a good heat storage capability, and so they can be utilized, in particular, to compensate for temperature fluctuations.

If plastics are used as material for the micro heat exchanger and container, it is necessary to apply a coating that protects the plastic from the temperatures of the exhaust gas flowing through the micro heat exchanger. Such coatings are also referred to as “thermal barrier coating”. On account of the high temperatures of the exhaust gas, it is necessary to coat all surfaces of the micro heat exchanger composed of the plastics material.

The external dimensions of the micro heat exchanger used according to the invention are preferably from 60×60×20 to 40×40×8 mm³.

The specific heat transfer area of the micro heat exchanger, in relation to the volume of the micro heat exchanger, is preferably from 0.1 to 5 m²/l, particularly preferably from 0.3 to 3 m²/l, in particular from 0.5 to 2 m²/l.

Suitable micro heat exchangers are commercially available, for example from the Institut für Mikrotechnik Mainz GmbH. The IMM offers various geometries of microstructured heat exchangers, and in particular microstructured high-temperature heat exchangers for a maximum operating temperature of 900° C. These high-temperature heat exchangers have dimensions of about 80×50×70 mm³ and function (for other applications) according to the counterflow principle. They have a pressure loss of less than 50 mbar and a specific heat transfer area of about 1 m^{2/l .}

Other micro heat exchangers are exhibited by VDI/VDE-Technologiezentrum Informationstechnik GmbH (www.nanowelten.de). Micro heat exchangers are furthermore offered by Ehrfeld Mikrotechnik BTS GmbH, Wendelsheim and SWEP Market Services, a branch of Dover Market Services GmbH, Fürth.

The micro heat exchanger known from the above sources must be adapted for use in the thermoelectric module according to the present invention. Thus, an integrally molded container has to be preformed or formed on the micro heat exchanger. Typically, the assembly of micro heat exchanger and thermoelectric module is a “one piece” component which is preferably obtained in one process by Selective Laser Sintering (SLS).

The micro heat exchanger is thus connected to the thermoelectric module in a way which has the best possible thermal conduction. It is thus thermally conductively connected directly to the thermoelectric module.

The pressure loss generated through the continuous channels of the heat exchanger for a gas flowing through is preferably at most 100 mbar, in particular at most 50 mbar. Such pressure losses do not lead to an increased fuel consumption of the internal combustion engine. Such a pressure loss can be realized, in particular if the micro heat exchangers are arranged such that the channels through which the exhaust gas flows run parallel and are connected to an inlet on one side and to an outlet on the other side. The length of the channels through which the exhaust gas flows is in this case preferably at most 60 mm, in particular at most 40 mm. If more than one micro heat exchanger is used, the micro heat exchangers are likewise connected in parallel and connected to a common inlet and a common outlet, such that the channels of the individual heat exchangers likewise run parallel.

The heat-exchanging surface of the micro heat exchanger may be installed directly in the exhaust system or tailpipe of an internal combustion engine, in particular of a motor vehicle. It may in this case be installed fixed or removably. The heat-exchanging surface is preferably firmly encapsulated with the thermoelectric module.

If the micro heat exchanger is provided with a washcoat of the catalyst material, it may be installed in the exhaust system at the position of the original exhaust gas catalytic converter. In this way, a high exhaust gas temperature can be supplied to the micro heat exchanger. The temperature may be increased even further by the chemical conversion at the exhaust gas catalyst of the micro heat exchanger, so that much more efficient heat transfer takes place than in known systems.

An improved efficiency of the thermoelectric module is also achieved by the improved heat flux, due to the integrated assembly of microheat exchanger and thermoelectric module.

A protective layer for protecting against excessive temperatures may furthermore be provided inside the container next to the micro heat exchanger. This layer, also referred to as a phase-change layer, is preferably made of inorganic metal salts or metal alloys having a melting point in the range of from 250° C. to 1700° C. Suitable metal salts are for example fluorides, chlorides, bromides, iodides, sulfates, nitrates, carbonates, chromates, molybdates, vanadates and tungstates of lithium, sodium, potassium, rubidium, cesium, magnesium, calcium, strontium and barium. Mixtures of suitable salts of this type, which form double or triple eutectics, are preferably used. They may also form quadruple or quintuple eutectics.

Alternatively, it is possible to use metal alloys as phase-change materials and combinations thereof, which form double, triple, quadruple or quintuple eutectics, starting from metals such as zinc, magnesium, aluminum, copper, calcium, silicon, phosphorus and antimony. The melting points of the metal alloys should in this case lie in the range of from 200° C. to 1800° C.

The thermoelectric module may be encapsulated with the protective layer, in particular when using metals such as nickel, zirconium, titanium, silver and iron, or when using alloys based on nickel, chromium, iron, zirconium and/or titanium.

One or more of the thermoelectric modules, for example connected in succession, may be integrated into the exhaust system of the internal combustion engine. In this case, thermoelectric modules comprising different thermoelectric materials may also be combined.

As indicated above, the thermoelectric modules comprise the hot side electrically conductive contacts, p- and n-conducting thermoelectric material pieces, cold side electrically conductive contacts and cold side electrical insulation. This insulating layer may be formed of ceramics, glass, glimmer and other coatings.

Furthermore, it is possible to fill the spaces between the p- and n-conducting thermoelectric materials with an insulating filler which can be again formed of ceramics, glass, glimmer or other insulating materials. These materials, when pressed between the p- and n-conducting thermoelectric materials can again increase the mechanical stability of the thermoelectric module.

The invention also relates to the use of a thermoelectric module as described above in the exhaust system of an internal combustion engine, preferably in a motor vehicle such as an automobile or truck. In this case, the thermoelectric module is used in particular for generating electricity from the heat of the exhaust gas.

When there is a washcoat on the micro heat exchanger, however, the thermoelectric module may also be used in reverse for preheating the exhaust gas catalyst during a cold start of an internal combustion engine, preferably of a motor vehicle. In this case, the thermoelectric module is used as a Peltier element. When a voltage difference is applied to the module, the module transports heat from the cold side to the hot side. The preheating of the exhaust gas catalyst due to this reduces the cold start time of the catalyst.

The invention furthermore relates to an exhaust system of an internal combustion engine, preferably of a motor vehicle, comprising one or more thermoelectric modules as described above, integrated into the exhaust system

In this case, the exhaust system is intended to mean the system which is connected to the outlet of an internal combustion engine and in which the exhaust gas is processed.

The thermoelectric module according to the invention has many advantages. The pressure loss in the exhaust system of an internal combustion engine is low, in particular when the micro heat exchanger is coated with a washcoat of the exhaust gas catalyst. The structure of the exhaust system can be simplified significantly by the one integrated component. Since the integrated component can be integrated closer to the internal combustion engine in the exhaust system, higher exhaust gas temperatures can be supplied to the thermoelectric module. By the reverse use of the thermoelectric module as a Peltier element, the exhaust gas catalyst can be heated during a cold start of the engine.

Exemplary embodiments of the invention are explained in greater detail in the following examples:

### EXAMPLES

In the examples n-type Mg₂Si, p-type MnSi_{1.7} and n-type (Ti,Zr,Hf)NiSn (half-Heusler) were employed. Firstly, thermoelectric material pieces with dimensions 5 mm×5 mm×7.5 mm were produced according to known processes.

As the electrically conductive contacts, single sided aluminum clad mild steel (Feran®) was used. The Feran® thickness was 0.6 mm with 0.25 mm of aluminum and 0.35 mm of steel.

The thermo-compression bonding was performed in an inert-reductive gas atmosphere of argon, argon/5% hydrogen or nitrogen.

The three different thermoelectric material pieces were placed on a Feran® disc with an aluminum surface facing the thermoelectric material pieces. Two Feran® discs were placed on top and below 5 mm×5 mm faces of the samples.

The cover gas was led in an amount of 5 ml/min. The pressure during thermo-compression bonding was 400 bar (abs.). After a first trial with argon/5% hydrogen, a maximum temperature of 628° C. and a hold time of 45 min. at the maximum temperature, followed by a temperature decline over 20 hours to room temperature was employed. The three samples were afterwards each cut from the circular Feran® disc and each one was held in a vice whilst the sample was loaded with a weight in steps of 100 g. Each sample was loaded to fracture and then the fracture surfaces examined.

The bond strengths were calculated from the bonding area and the loading. The following results were obtained:

TABLE 1
Strength Estimates of TCB Bonds

| Sample Indent | Breaking Load (kg) | Bond Strength MPa |
|---|---|---|
| Mg₂Si | 1 | 0.4 |
| half-Heusler | 1 | 3.0 |
| MnSi_{1.7} | 1.2 | 0.53 |

The geometry of the bonded samples limited the ability to perform an accurate measurement of the bond strength and therefore the above data can only be judged as a crude estimate of the bond strengths.

In the second bonding run the maximum temperature was lowered to 614° C. and a shorter hold time of 15 minutes was applied.

In a third bonding run, a pure nitrogen environment was employed at a 5 l/min. flow rate with maximum temperature of 590° C. and hold time of 15 minutes.

In the fourth run, the same maximum temperature and hold up time were employed in an argon/5% hydrogen atmosphere.

In a fifth run a slightly lower temperature of 570° C. was employed for 15 minutes.

The resistance of the thermoelectric legs thus formed was determined after cutting the Feran® discs so that each thermoelectric material piece was separate.

The resistance of the different thermoelectric material legs including the contacts was in the range of from 10 to 20 mOhms.

From the above results it is evident that thermo-compression bonding was a suitable way for obtaining bondings between electrically conductive contacts and thermoelectric material pieces with low resistance and high mechanical strength.

Thermoelectric module:

A module made up of n-type Mg₂Si and p-type MnSi_{1.7} in a temperature gradient from 550° C. hot side to 50° C. cold side produced a specific power of 0.75 W/cm2.

A module made up of n-type half-Heusler and p-type MnSi_{1.7} in a temperature gradient from 550° C. hot side to 50° C. cold side produced a specific power of 0.70 W/cm2.

Both measurements have been performed under Ar atmosphere.

1. A process for forming a thermo-electric module comprising p- and n-conducting thermoelectric material pieces which are ultimately connected to one another via electrically conductive contacts, the process comprising connecting
electrically conductive contacts of an electrically conductive contact material being one electrically conductive material cladded on another electrically conductive material to the thermoelectric material pieces by thermo-compression bonding.

2. The process according to claim 1, wherein the electrically conductive contact material is a composite material of two or more of Al, Cu, Ag, Au, Fe, Mo, Si, Pd, Cr, Co, Ni, Ti, W and an alloy.

3. The process according to claim 2, wherein the electrically conductive contact material is aluminum clad steel.

4. The process according to claim 3, wherein the aluminum clad steel is single sided aluminum clad mild steel.

5. The process according to claim 1, wherein the thermoelectric material is chosen from silicides and half-Heusler materials.

6. The process according to claim 1, wherein the thermoelectric material pieces are coated with metals or metal alloys chosen from Al, Cu, Ag, Au, Fe, Mo, Si, Pd, Cr, Co, Ni, Ti, W, and stainless steel before connecting the electrically conductive contacts thereto.

7. A thermoelectric module comprising of p- and n-conducting thermoelectric material pieces which are alternately connected to one another via electrically conductive contacts, wherein the electrically conductive contacts of an electrically conductive contact material being one electrically conductive material cladded on another electrically conductive material are connected to the thermoelectric material pieces by thermo-compression bonding.

8. The thermoelectric module according to claim 7, wherein the electrically conductive contact material is a composite material of two or more of Al, Cu, Ag, Au, Fe, Mo, Si, Pd, Cr, Co, Ni, Ti, W and an alloy.

9. The thermoelectric module according to claim 8, wherein the electrically conductive contact material is aluminum clad steel.

10. The thermoelectric module according claim 7, wherein the thermoelectric material is chosen from silicides and half-Heusler materials.

11. The thermoelectric module according to claim 7, wherein the thermoelectric module is thermally conductively connected to a micro heat exchanger which comprises a plurality of continuous channels having a diameter of at most 1 mm, through which a fluid heat exchanger medium can flow.

12. The thermoelectric module according to claim 11, wherein the channels of the micro heat exchanger are coated with a washcoat of a motor vehicle exhaust gas catalyst

13. The thermoelectric module according to claim 7 for use in exhaust system of an internal combustion engine.

14. The thermoelectric module according to claim 13 for use in preheating the exhaust gas catalyst during a cold start of an internal combustion engine.

15. An exhaust system of an internal combustion engine, comprising one or more thermoelectric modules according to claim 7, integrated into the exhaust system.

16. The process according to claim 1, wherein the alloy is stainless steel.

17. The thermoelectric module according to claim 8, wherein the alloy is stainless steel.

18. The thermoelectric module according to claim 12, wherein the catalyst catalyzes at least one of the conversions: NO_{X} to nitrogen, hydrocarbons to CO₂ and H₂O, and CO to CO₂.

19. The process according to claim 5, wherein the thermoelectric material is chosen from from magnesium silicides (n-type), manganese silicides (p-type), half-Heusler compounds of the general formula (Ti_{1-x-y}ZrₓHf_{y})NiSn_{1-w}Sb_{w} with 0<=x and y<=1 and 0<=w<0.2 and Ti CoSb and substitution variants thereof.

20. The thermoelectric module according to claim 11, wherein the thermoelectric material is chosen from from magnesium silicides (n-type), manganese silicides (p-type), half-Heusler compounds of the general formula (Ti_{1-x-y}ZrₓHf_{y})NiSn_{1-w}Sb_{w} with 0<=x and y<=1 and 0<=w<0.2 and Ti CoSb and substitution variants thereof.

21. The thermoelectric module according to claim 7 for use in exhaust system of an internal combustion engine to generate electricity from the heat of an exhaust gas emitted from said exhaust system.

22. A method of generating electricity, the method comprising:
passing exhaust gas generated from an internal combustion engine over a thermoelectric module according to claim 7.
